(19) United States
(12) Patent Application Publication
(10) Pub. No.: US 2006/0040168 A1
(43) Pub. Date: Feb. 23, 2006

(54) Nanostructured fuel cell electrode

(75) Inventor: K. R. Sridhar, Los Gatos, CA (US)

Correspondence Address: FOLEY AND LARDNER LLP;SUITE 500, 3000 K STREET NW, WASHINGTON, DC, 20007, US

(73) Assignee: Ion America Corporation

(21) Appl. No.: 11/207,018

(22) Filed: Aug. 19, 2005

Related U.S. Application Data
(60) Provisional application No. 60/602,891, filed on Aug. 20, 2004.

(51) Int. Cl. H01M 4/86; H01M 8/12; C01B 13/14; C30B 23/00; C23C 16/00

(52) U.S. Cl. 429/40; 427/115; 429/30; 423/592.1; 75/952; 427/569; 117/84

(57) ABSTRACT

A fuel cell includes an electrolyte, a first electrode, and a second electrode. At least the first electrode comprises a nanostructured material.

### BACKGROUND OF THE INVENTION

This application claims benefit of priority of U.S. Provisional Application Ser. No. 60/602,891, filed Aug. 20, 2004, which is incorporated herein by reference in its entirety.

The present invention is generally directed to fuel cell materials and more specifically to nanowire and other nanostructured electrode materials for solid oxide fuel cells.

Fuel cells are electrochemical devices which can convert energy stored in fuels to electrical energy with high efficiencies. One type of high temperature fuel cell is a solid oxide fuel cell which contains a ceramic (i.e., a solid oxide) electrolyte, such as a yttria stabilized zirconia (YSZ) electrolyte. An anode electrode is formed on one side of the electrolyte and a cathode electrode is formed on the opposite side of the electrolyte. In a non-reversible fuel cell, the anode electrode is exposed to the fuel flow, such as hydrogen or hydrocarbon fuel flow, while the cathode electrode is exposed to oxidizer flow, such as air flow. In operation, oxygen ions diffuse through the electrolyte from the cathode side to the anode side and recombine with hydrogen and/or carbon on the anode side of the fuel cell to form water and/or carbon dioxide.

In the prior art fuel cells, the anode material may comprise a nickel-YSZ or a copper-YSZ cermet layer and the cathode material may comprise a conductive ceramic layer, such as strontium doped lanthanum manganite (LSM) or strontium doped lanthanum chromite (LSC), or metals or metal alloys, such as silver palladium alloys, chromia forming metals, and/or platinum. However, oxygen diffusion through these electrode layers or thin films is lower than desired.

### BRIEF SUMMARY OF THE INVENTION

One preferred aspect of the present invention provides a fuel cell comprising an electrolyte, a first electrode, and a second electrode. At least the first electrode comprises a nanostructured material.

Another preferred aspect of the present invention provides a method of forming a plurality of metal nanostructures, comprising forming a plurality of metal oxide nanostructures on a substrate, and annealing the nanostructures in a reducing atmosphere to convert the metal oxide nanostructures to metal nanostructures

Another aspect of the present invention provides a method of making metal oxide nanowires, comprising providing a mixture of a first metal oxide source material and a second material with a lower melting point than the metal oxide source material, sublimating the first and the second materials to provide a nanowire source vapor, and growing the metal oxide nanowires on a substrate from the source vapor.

Another preferred aspect of the present invention provides a method of making metal oxide nanowires, comprising providing an oxygen flux onto a metal substrate to form metal oxide nucleation regions, and providing additional oxygen flux to the nucleation regions to form the metal oxide nanowires at the nucleation regions.

### BRIEF DESCRIPTION OF THE DRAWINGS

FIGS. 1 and 3 are schematic side cross sectional views and FIG. 2 is a three dimensional perspective view of nanostructures according to aspects of the present invention.

FIGS. 4A and 4B are schematic side views of steps in a method of making nanowires according to an aspect of the present invention.

FIG. 5 is a schematic side cross sectional view of a fuel cell stack according to an aspect of the present invention.

### DETAILED DESCRIPTION OF THE PREFERRED EMBODIMENTS

The present inventor has realized that oxygen diffusion through an electrolyte in a solid oxide fuel cell proceeds between so-called “three phase boundaries.” These three phase boundaries are electrolyte grain boundary regions at the boundary of an electrode (i.e., cathode or anode) and electrolyte. Diffusing oxygen makes up the third “phase.” The present inventor has realized that if one or both electrodes in the fuel cell are formed from nanostructured material, then the surface area between the electrolyte and the electrode contacting the electrolyte surface is increased compared to thin film electrodes. The increased surface area results in more three phase boundary regions, which allows more oxygen to diffuse through the electrolyte. This increases the power density (i.e., watts per cm²) of the fuel cell and decreases the cost per watt of the fuel cell.

The term nanostructured material includes quasi-one dimensional nanostructured materials, such as nanowires, nanorods and nanotubes, and quasi-two dimensional nanostructured materials, such as nanobelts and nanoribbons. Nanowires and nanotubes preferably have a substantially cylindrical shape. The cylinder height is much greater than its diameter, such as at least 10 times, preferably at least 100 times greater. The nanowire or nanotube diameter is preferably less than 500 nm, preferably less than 50 nm. Thus, nanowires and nanotubes are considered quasi-one dimensional nanostructures because they extend substantially in one dimension due to their nanoscale diameter. Nanowires differ from nanotubes in that nanotubes have a hollow core while nanowires have a solid core. Nanorods may have a hollow or a solid core, but differ from nanowires and nanotubes in that they do not necessarily have a cylindrical shape. Preferably, the nanowires, nanorods and nanotubes have a width (i.e., diameter for nanowires and nanotubes) between 10 and 300 nm, such as between 50 and 150 nm, and a height less than 20 microns, such as between 0.2 and 5 microns, for example between 0.5 and 1.5 microns.

Nanobelts and nanoribbons are examples of quasi-two dimensional nanostructures. Nanobelts and nanoribbons are considered quasi-two dimensional nanostructures because they extend substantially in two dimensions due to their nanoscale thickness. For example, nanobelts and nanoribbons may have a thickness that is much smaller than their width and length, such as at least 2 to 10 times smaller. For example, the nanobelt and nanoribbon thickness is preferably less than 50 nm, such as 10-30 nm for example. The nanobelt or nanoribbon width may be between 20 nm and 1 micron, such as between 50 and 150 nm for example, and the nanobelt or nanoribbon length may be 50 nm to 1 cm, such as 0.5-100 microns, for example.

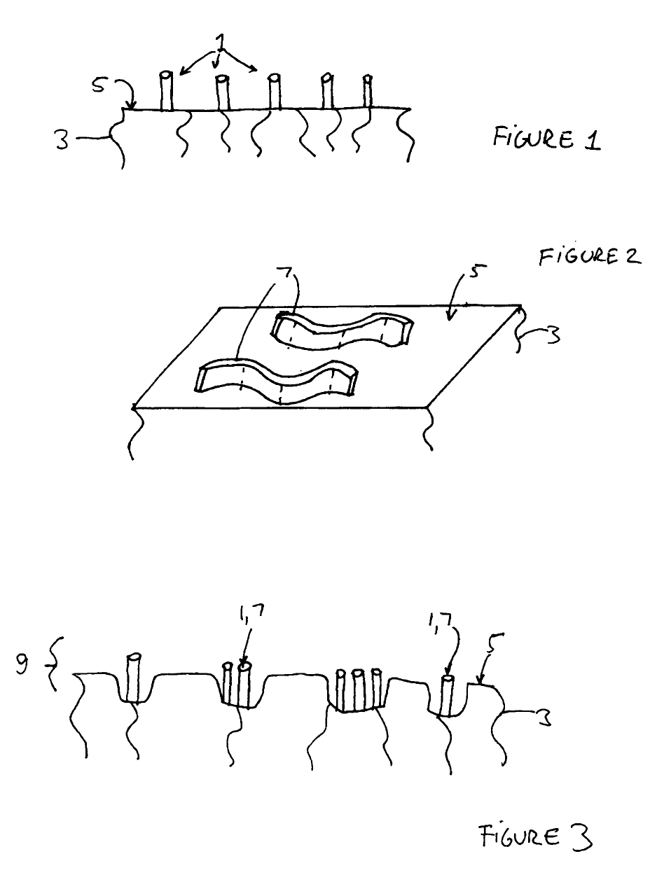

Preferably, the nanostructures extend substantially perpendicular to the electrolyte surface. The term substantially perpendicular includes deviation of 1-20 degrees from the normal to the electrolyte surface on which the nanostructures are formed. In other words, as shown in FIG. 1, the axis of the quasi-one dimensional nanostructures 1, such as nanowires, nanotubes and nanohorns, extends substantially perpendicular to the electrolyte 3 surface 5. As shown in FIG. 2, the width of the quasi-two dimensional nanostructures 7, such as nanobelts and nanoribbons, extends substantially perpendicular to the electrolyte 3 surface 5. The nanobelt or nanoribbon thickness (smallest dimension) and length (largest dimension) extend substantially parallel to the electrolyte 3 surface 5. In other words, the nanobelts and nanoribbons are preferably positioned on their “edge” on the electrolyte surface. However, if desired, some or all of the quasi-one and quasi-two dimensional nanostructures may be formed parallel to the electrolyte surface 5. In this case, the nanostructures lie flat on the electrolyte surface 5.

In one aspect of the present invention, the electrolyte 3 surface 5 supporting the nanostructures 1, 7 is flat. However, as shown in FIG. 3, in another aspect of the present invention, the electrolyte surface 5 is a non-uniform surface, such as a textured or grooved surface. Preferably, at least the active portions of one or both major surfaces 5 of the electrolyte 3 are made non-uniform. In this case, the surface area between the electrolyte 3 and the nanostructure 1, 7 containing electrode 9 contacting the non-uniform surface 5 is increased. The “active portion” of the electrolyte is the area between the electrodes that generates the electric current. In contrast, the peripheral portion of the electrolyte is used for attaching the electrolyte to the fuel cell stack and may contain fuel and oxygen passages. Preferably, the nanostructures 1, 7 are selectively located in the grooves or recesses 11 in the electrolyte 3 surface 5, as shown in FIG. 3. The electrolyte surface or surfaces 5 may be textured or grooved by any suitable method, such as by laser ablation, lapping, grinding, polishing or etching, as described for example in U.S. Published Application 2003/0162067, incorporated herein by reference in its entirety.

The nanostructures 1, 7 may comprise any suitable fuel cell electrode materials. Preferably, the nanostructures comprise any suitable solid oxide fuel cell electrode materials. For example, the anode materials may comprise nickel (including essentially pure nickel and nickel alloys where nickel comprises greater than 50 weight percent of the alloy), copper (including essentially pure copper and copper alloys), metal cermets, such as Ni-YSZ and Cu-YS cermets, noble metals (including essentially pure noble metals and alloys), such as Ag, Pd, Pt and Ag—Pd or Ag—Pt alloys, chromium alloys, such as a proprietary high chromium anode alloy manufactured by Plansee AG of Austria, and conductive ceramics, such as strontium doped lanthanum chromite (LSC). For example, cathode materials may comprise conductive ceramics, such as strontium doped lanthanum manganite (LSM), strontium doped lanthanum chromite (LSC) and strontium doped lanthanum cobaltite (LSCo) and noble metals (including essentially pure noble metals and their alloys), such as an Ag—Pd alloy. The electrolyte material may comprise any suitable ceramic material, such as YSZ or a combination of YSZ with another ceramic such as doped ceria.

The nanostructures may be made by any suitable method. For example, the nanostructures may be made by laser ablation, chemical vapor deposition (CVD) or physical vapor deposition (PVD). In laser ablation, a laser ablates a source material from a target which then condenses on the electrolyte as the nanostructures. The ceramic nanostructures may be made by laser ablation from a ceramic target (see for example Y. F. Zhang, et al., 323 Chem. Phys. Lett. (2000) 180-184, incorporated herein by references, which describes YBaCuO nanorod formation by laser ablation). In chemical vapor deposition, a catalyst material, such as a metal catalyst material, is first deposited on the electrolyte. The vaporized reactants are then delivered to the catalyst covered electrolyte to form the nanostructures. For example, one preferred nanostructure CVD method uses the vapor-liquid-solid (VLS) mechanism to form nanostructures such as nanowires. The diameter distribution of the nanowires may be controlled by controlling the size distribution of the catalyst particles or the thickness of the catalyst layer. In physical vapor deposition, the catalyst may be omitted and the reactants are evaporated from a source and condense on the electrolyte as the nanostructures.

If metal nanostructures are formed on the electrolyte, then these metal nanostructures are preferably first formed as metal oxide nanostructures and then reduced to metal nanostructures by annealing in a reducing atmosphere. This may simplify the metal nanostructure fabrication process. For example, nickel (i.e., pure nickel or nickel alloy) nanostructures, such as nickel nanowires, may be first formed as nickel oxide nanowires on the electrolyte. The nickel oxide nanowires are then reduced to nickel nanowires either during the first operational run of the fuel cell stack or during a special reducing anneal of the fuel cell prior to operation. Any suitable reducing atmosphere may be used for the anneal, such as a hydrogen, forming gas or a hydrogen/hydrocarbon atmosphere.

The following methods describe formation of nickel oxide nanowires for use as an anode of a solid oxide fuel cell. It should be understood that similar methods may be used to make other nanostructures from nickel or other materials, either for anode and/or for cathode electrodes for solid oxide and/or for other types of fuel cells. Furthermore, it should be noted that the nickel oxide (i.e., metal oxide) nanowires may be converted to nickel (i.e., essentially pure nickel or nickel alloy) nanowires by annealing the nanowires in a reducing atmosphere.

The nickel oxide nanowires may be made in any suitable apparatus, such as a CVD or PVD apparatus. Preferably, the nanowires are made in a CVD apparatus. The CVD apparatus includes a quartz tube or other appropriate deposition chamber with a nickel or nickel oxide source, an optional oxygen source (needed if a nickel rather than a nickel oxide source is used) and an optional carrier gas to carry the mixture of source gases/vapors. The reactant and carrier sources may comprise gas conduits, pipes or inlets which provide the reactant and carrier gas sources into the deposition chamber. Alternatively, the reactant source may comprise an open container containing liquid or solid reactant source(s), located in the deposition chamber. The apparatus also includes a heating system to elevate the temperature of one or more substrates located in the reaction chamber to the reacting temperature level. The heating system may comprise a resistive, RF or heat lamp heating system. Prior to nanowire deposition, one or more substrates are inserted into the reaction chamber. The carrier and reactant gases are then introduced into the reaction chamber and the nickel oxide nanowires are formed on the substrate(s). For fuel cell electrode fabrication, the substrate(s) comprise the fuel cell electrolyte(s). The electrolyte(s) are positioned in the deposition chamber such that the nanowires are formed only on one side of the electrolytes. For example, the electrolyte(s) are preferably positioned in a boat, on a susceptor or on other substrate support such that the carrier and reactant gas flow impinges only on one major surface of the electrolyte(s). For anode nanowire deposition, the gas flow impinges on the anode major surface (i.e., the anode face) of the electrolyte(s).

The substrate(s) preferably, but not necessarily, have a catalyst deposited on their growth surface. For example, the catalyst may comprise a thin layer, such as a 1 to 10 nm layer of gold or other appropriate metal such as Ga, Fe or Co. The catalyst may also be in the shape of discrete metal islands. The catalyst layer can be deposited by sputtering, thermal evaporation, laser deposition or any other thin film deposition technique. The choice of metal is dictated by the immiscibility of this metal with nickel and nickel oxide. The following are alternative CVD methods for forming nickel oxide nanowires on one or more substrates.

In the first method, a metallic nickel source in any suitable form is melted in an flowing oxygen atmosphere. Nickel is heated above 1455° C. because its melting point is about 1455° C. If a nickel alloy is used, then the temperature may be somewhat higher or lower. The substrate(s) are heated to the deposition temperature, preferably to a temperature sufficient to melt the thin catalyst layer to the liquid or semi-solid state. Nickel vapor and oxygen reach the substrate, such as an electrolyte containing a thin gold film (which preferably melted to form gold drops) on its anode face to form the nickel oxide nanowires. In this method, a separate carrier gas is not required because oxygen acts as a carrier gas.

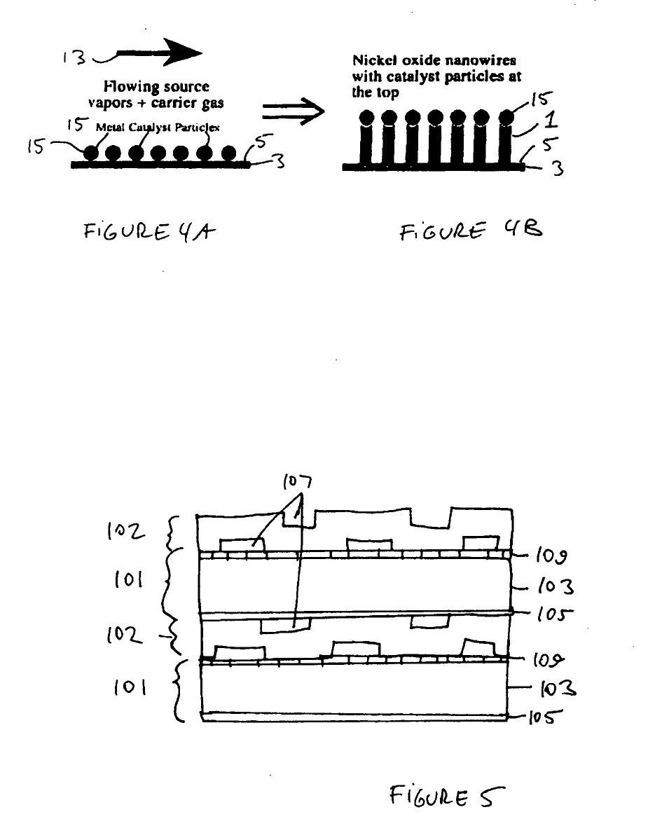

In this first method, the nanowire growth would occur following the VLS (vapor-liquid-solid) approach, as shown schematically in FIGS. 4A and 4B. The source vapor 13, such as nickel and oxygen, dissolves into the metal catalyst 15 which, at the deposition temperature, would be in the form of liquid drops, as shown in FIG. 4A. When the dissolution of the vapor in the catalyst drop reaches a supersaturation level, then nickel oxide nucleation occurs and the nickel oxide material will crystallize out of the catalyst particle and continue to grow axially to form a nickel oxide nanowire 1. As shown in FIG. 4B, the nanowires 1 extend perpendicular to the electrolyte 3 substrate. The catalyst 15 particles are located at the tips (i.e., the top) of the nanowires 1.

In an alternative second method, the nickel source is replaced with a nickel oxide source. The nickel oxide source may be a solid block or a powder source. The nickel oxide is heated to its sublimation point, and nickel oxide vapor 13 flows over the substrate with the catalyst metal 15. Nickel oxide nanowires 1 grow at the electrolyte 3 substrate according to the mechanism described above. In this method, an inert carrier gas, such as nitrogen or argon, or an oxygen carrier gas may be used to transport the nickel oxide vapor.

In an alternative third method, nickel oxide is mixed with carbon. For example, the nickel oxide and carbon may be provided as a mixture of nickel oxide and carbon powders. The nickel oxide and carbon source is heated to about 700-1000° C. which produces nickel vapor and carbon monoxide gas:
NiO₍ₛ₎+C₍ₛ₎→Ni₍ᵥ₎+CO_{(g)}

The nickel vapor and carbon monoxide gas mixture flows over the electrolyte substrate covered with the catalyst. The nickel vapor reacts with the catalyst such that the nickel oxide nanowire grows out of the catalyst:
Ni₍ᵥ₎+X₍ₛ₎→Ni−X₍ₗ₎
Ni−X₍ₗ₎+CO_{(g)}→X−NiO₍ₗ₎+CₓO_{y(g)}
where X is the catalyst metal.

In an alternative fourth method, an organic nickel compound is used as a nickel source. For example, nickel acetate may be used as the nickel source. Nickel acetate may be heated to its sublimation point and the sublimed vapor is provided into an oxygen carrier gas. The nickel vapor along with oxygen flow over the catalyst covered substrate to provide nanowire growth out of the catalyst. Other organic nickel compounds, such as compounds that are in a liquid state at room temperature, may also be used if desired.

An alternative fifth method does not use a catalyst or the VLS mechanism. The fifth method uses a nanopore array template to form the nanowire array, where nanowires of desired shape are formed by using nanopores of the corresponding size. A template nanopore array, such as a layer of an alumina or other material that can withstand oxidation temperatures, and which contains nanopores, is formed on the substrate, such as an electrolyte substrate. The pore diameter of the template is chosen to match the desired diameter of the nanowires. In other words, a nanopore array with an average pore diameter of about 30 nm may be used to form nanowires having an average diameter of about 30 nm. Nickel is then deposited into the pores by any suitable method. For example, nickel can be deposited inside the pores by any suitable physical deposition methods, such as sputtering (ion beam sputtering, magnetron sputtering), thermal evaporation or laser deposition, such as laser ablation. If nickel is deposited over the edges of the pores, then the nanopore array may be subjected to a planarization step, such as a chemical mechanical polishing step, which removes nickel that protrudes above and over the pores. In other words, the nanopore material is used as a polish stop to leave the nickel nanowires inside the nanopores.

In an alternative nickel deposition method, nickel is selectively deposited inside the nanopores electrochemically using nickel containing electrolytes. If desired, a seed layer may be deposited on the substrate below the nanopore array to facilitate the selective nickel deposition on the seed layer exposed in the pores. The seed layer may be a metal layer, such as a nickel, gold or silver layer, for example. Also, a voltage or current may be applied to the seed layer to facilitate the electrodeposition of the nickel in the pores. After the nickel deposition inside the pores is complete, nickel may be oxidized by heating it in an oxidizing atmosphere (flowing or stationary oxygen) which forms the nickel oxide nanowires inside the pores. Otherwise, the oxidation may be omitted. The template surrounding the nanowires may be selectively removed by selective etching to expose the nanowires.

Alternatively, after forming a template nanopore array on the electrolyte substrate, the electrolyte substrate is selectively etched using the nanopore array as a mask. For example, the electrolyte is anisotropically or isotropically etched using a wet (i.e., liquid) or dry (i.e., gas or plasma) etching medium which selectively etches the portions of the electrolyte exposed in the nanopores of the array. Thus, the nanopore array pattern is transferred to the electrolyte to form a nanoporous surface in the electrolyte. The nanopore pattern in the electrolyte preferably contains nanopores with a substantially uniform nanopore diameter distribution, such as a diameter distribution which deviates from a desired mean or median diameter by less than 0.5 to 5 percent within one standard deviation. The mean or median nanopore diameter may be 10 to 300 nm for example.

The nickel nanowires are then formed in the nanopores in the electrolyte. The template nanopore array may be removed by selective etching before or after the nanowire formation, or be left on the electrolyte if desired. If anisotropic etching is used to form the nanopore array in the electrolyte, then the nanowires a formed flush with the electrolyte nanopore sidewalls. If anisotropic etching is used, then a space may exist between the nanowires and electrolyte nanopore sidewalls.

It should be noted that metal nanowires other than nickel containing nanowires may be formed using the above mentioned methods. Thus, any suitable nanowires, such as noble metal nanowires (i.e., Au, Ag, Pt, Pd, their alloys, etc.), transition metal nanowires (i.e., Fe, Co, W, their alloys, etc.) and other metal nanowires (i.e., Al, its alloys, etc.) may be formed on a substrate using the above mentioned methods. In other words, metal rather than metal oxide nanowires may be formed by either converting metal oxide nanowires to metal nanowires by annealing the metal oxide nanowires in a reducing atmosphere or by directly forming metal nanowires in nanopores in a substrate. Also, while a ceramic fuel cell electrolyte is a preferred substrate, other substrates, such as semiconductor, metal, glass, ceramic, quartz or plastic substrates may be used. The substrates may be incorporated into various electronic, biomedical or mechanical devices and products as desired.

FIG. 5 illustrates a solid oxide fuel cell stack 100 incorporating a plurality of fuel cells 101, such as solid oxide fuel cells (including regenerative or a non-regenerative solid oxide fuel cells), separated by interconnects 102. Each solid oxide fuel cell 101 comprises a plate shaped fuel cell comprising a ceramic electrolyte 103, a cathode electrode 105 located on a first surface of the electrolyte and an anode electrode 109 located on a second surface of the electrolyte. The interconnect 102 comprises an electrically conductive material, such as a metal or a conductive ceramic. The interconnects 102 electrically contact the anode 109 and cathode 105 electrodes of the fuel cells 101. One or both electrodes 105 and 109 may contain the nanostructured material, such as the nickel containing nanowires, described above. The electrodes 105 and 109 of each planar fuel cell 101 are located on the opposite face of the electrolyte 103. However, if desired, tubular rather than planar fuel cells may be used instead. The interconnects 102 preferably contain gas flow grooves 107 since the interconnects also act as gas separation plates in the stack 100. The interconnects 102 may also have optional conductive contacts which extend to contact the electrodes 105 and 109. The fuel cells also contain various contacts, seals and other components which are omitted from FIG. 5 for clarity.

Another embodiment of the invention provides a method of forming metal oxide nanostructures at a lower temperature than a typical vapor-liquid-solid (VLS) approach. These nanostructures include nanostructures made from high sublimation temperature ceramic materials which are the same as or similar to the solid oxide fuel cell electrolyte material, such as zirconium oxide nanowires. These nanostructures may be formed on one or more electrolyte surfaces to provide one or more non-uniform electrolyte surfaces. Fuel cell electrodes are then formed over these non-uniform surfaces.

In principle, zirconium oxide (i.e., zirconia) nanowires can be grown using the above described vapor-liquid-solid (VLS) approach. The source material can be zirconium oxide itself in a powder form. The substrate may be a zirconia substrate (i.e., such as a stabilized or unstabilized zirconia substrate, for example a YSZ substrate) or a compatible high temperature tolerant substrate. A catalyst layer may be formed on the substrate to promote the VLS growth. This catalyst layer can be gold, or similar noble metals or alloys or low melting materials, such as indium or gallium. The VLS growth can be carried out in a reactor which consists of a high temperature furnace, a tube suitably made of a high temperature material, and a high temperature crucible that holds zirconium oxide source powder. Since zirconium oxide sublimation temperature is very high (melting point 2715° C., sublimation at substantially higher temperatures), most of the reactor components must be made of materials that can withstand this very high temperature. In addition to the need to build a robust, high temperature reactor, the thermal budget for this process is expected to be extremely high.

The present inventor realized that if the zirconium oxide (i.e., zirconia) source powder is mixed with a low melting temperature material, such as indium (melting point of about 150 degrees centigrade), gallium or other similar low melting point materials, then this will bring the sublimation temperature of the mixture substantially lower to make the thermal budget and the growth process more economical. Also, since the indium or gallium or any other low melting metal mixed with zirconia can serve as the catalyst, there may not be a need to apply this or any other catalyst metal layer on the substrate to facilitate VLS growth. Alternatively, a separate catalyst layer, such as Au, In, Ga, etc. is formed on the growth substrate to be used with the VLS growth. Any low melting temperature material or a plurality of materials, such as pure metals and alloys, with a melting point temperature of 450° C. or less, such as 200° C. or less, including but not limited to tin, lead, sodium, lithium or zinc and their alloys, can be mixed with the ZrO powder. Preferably, these metals have a sublimation temperature below the zirconia nanowire growth temperature, such that these materials evaporate during the nanowire formation and are thus not present in significant quantities in the nanowires or on the substrate. It should be noted that the zirconia may be an undoped or unstabilized zirconia or it may be a doped or stabilized zirconia, such as yttria or scandia stabilized zirconia. The powder containing the high melting point material and a low melting point material is used as a source material. The powder is sublimated into a source vapor, similar to that shown in FIGS. 4A and 4B. The source vapor is then used to form the nanowires on the growth substrate, such as the electrolyte.

In another aspect of this embodiment, metal oxide nanowires, such as zirconia nanowires can be formed at a low temperature by the following method. A metal substrate, such as a zirconium substrate in a shape of a plate or foil, for example, is provided. Zirconium alloys, as well as metals and alloys other than zirconium may also be used. For example, a zirconium alloy, such as a yttrium or scandium zirconium alloy may be used to form YSZ or SSZ nanowires. The zirconium containing substrate is exposed to a source of atomic oxygen. This exposure can be performed in vacuum or at atmospheric pressure in a reactor. The oxygen source can be a plasma (radio frequency plasma, direct current discharge, inductively coupled plasma, microwave plasma, electron cyclotron plasma, high temperature plasma torch, etc.), a focused oxygen beam, or electrochemically generated oxygen. The type of source will influence the construction of the reactor.

The atomic oxygen, upon impinging on zirconium, is expected to form zirconium oxide nucleation regions. These regions will grow further into nanowires upon receiving additional oxygen flux that creates the zirconium oxide molecules. Through controlling the temperature, atomic flux, etc., metal nanowire growth will be promoted instead of nuclei growing laterally into enlarging grains that lead to thin films. Thus, stabilized or unstabilized zirconia nanowires or other metal oxide nanowires would be produced.

Thus, zirconia nanowires may be formed on a surface of the electrolyte of a solid oxide fuel cell using one of the above described methods. After the nanowires are formed, the anode or cathode electrodes are formed over the nanowires to form a non-uniform electrolyte/electrode interface. For example, an anode material, such as a Ni-YSZ cermet may be formed over the nanowires on the anode side of the electrolyte and/or LSM or other electrically conductive ceramic material may be formed over the nanowires on the cathode side of the electrolyte.

The nanowires may comprise stabilized zirconia, such as yttria or scandia stabilized zirconia or an unstabilized zirconia (i.e., zirconium oxide). Furthermore, the methods described above are not limited to zirconia nanowires. Other metal oxide nanowires, such as yttria, scandia, ceria, etc. nanowires may be formed using the above described methods, except where the zirconium is fully or partially substituted with one or more of yttrium, scandium or cerium in the starting powder or substrate. Thus, the nanowire or other nanostructured material described above may be made the same as or similar to that of the electrolyte. For example, YSZ nanowires may be formed on a YSZ electrolyte, while ceria nanowires, such as gadolinia doped ceria (GDC) nanowires, may be formed over a GDC electrolyte. Furthermore, while the nanowires or other suitable nanostructures are described as being formed on a fuel cell electrolyte, they may be formed in any other suitable device where the nanowires are useful, such as the devices described above.

The foregoing description of the invention has been presented for purposes of illustration and description. It is not intended to be exhaustive or to limit the invention to the precise form disclosed, and modifications and variations are possible in light of the above teachings or may be acquired from practice of the invention. The description was chosen in order to explain the principles of the invention and its practical application. It is intended that the scope of the invention be defined by the claims appended hereto, and their equivalents.

What is claimed is:

1. A fuel cell, comprising:
an electrolyte;
a first electrode; and
a second electrode;
wherein at least the first electrode comprises a nanostructured material.

2. The fuel cell of claim 1, wherein the nanostructured material comprises at least one of quasi-one dimensional and quasi-two dimensional nanostructured material.

3. The fuel cell of claim 2, wherein the nanostructured material is selected from a group consisting of nanowires, nanotubes, nanorods, nanobelts and nanoribbons.

4. The fuel cell of claim 3, wherein the nanostructured material comprises nanowires.

5. The fuel cell of claim 4, wherein the nanostructured material comprises nickel nanowires.

6. The fuel cell of claim 4, wherein the nanostructured material comprises nickel oxide nanowires.

7. The fuel cell of claim 4, wherein an average diameter of the nanowires is between about 10 and about 300 nm and an average height of the nanowires is between about 0.2 and about 5 microns.

8. The fuel cell of claim 2, wherein the nanostructured material comprises metal oxide nanowires formed on an electrolyte surface and which extend substantially perpendicularly to the electrolyte surface.

9. The fuel cell of claim 2, wherein the fuel cell comprises a solid oxide fuel cell.

10. The fuel cell of claim 9, wherein the nanostructured material is formed on a textured, grooved or nanoporous electrolyte surface.

11. The fuel cell of claim 10, wherein the nanostructured material comprises nanowires formed inside nanopores of a nanopore array in the surface of the electrolyte.

12. The fuel cell of claim 10, wherein the nanostructured material comprises nanowires formed in grooves in a surface of the electrolyte.

13. The fuel cell of claim 1, wherein the first electrode comprises an anode electrode.

14. The fuel cell of claim 1, wherein both the first and the second electrodes comprise nanostructured materials.

15. A solid oxide fuel cell stack comprising a plurality of solid oxide fuel cells of claim 9 separated by a plurality of respective interconnects.

16. A method of forming a plurality of metal nanostructures, comprising:
forming a plurality of metal oxide nanostructures on a substrate; and
annealing the nanostructures in a reducing atmosphere to convert the metal oxide nanostructures to metal nanostructures.

17. The method of claim 16, wherein:
the substrate comprises a fuel cell electrolyte; and
the metal nanostructures comprise a fuel cell electrode.

18. The method of claim 17, wherein:
the nanostructures comprise nanowires; and
the electrode comprises an anode electrode formed on a first surface of the electrolyte.

19. The method of claim 18, wherein:
the metal oxide nanowires comprise nickel oxide nanowires;
the metal nanowires comprise nickel nanowires; and
the fuel cell comprises a solid oxide fuel cell.

20. A method of making metal oxide nanowires, comprising:
providing a mixture of a first metal oxide source material and a second material with a lower melting point than the first metal oxide source material;
sublimating the first and the second materials to provide a nanowire source vapor; and
growing the metal oxide nanowires on a substrate from the source vapor.

21. The method of claim 20, wherein the second material sublimation temperature is lower than the metal oxide nanowire growth temperature, such that the second material evaporates during nanowire growth.

22. The method of claim 21, wherein:
the metal oxide nanowires comprise zirconium oxide nanowires;
the first source material comprises a zirconium oxide powder; and
the second material comprises a metal or a metal alloy having a melting point temperature of 450 degrees Celsius or less.

23. The method of claim 20, wherein the substrate comprises a solid oxide fuel cell electrolyte.

24. The method of claim 20, wherein the second material comprises a catalyst for metal oxide nanowire growth.

25. The method of claim 20, wherein the second material comprises indium or gallium.

26. A method of making metal oxide nanowires, comprising:
providing an oxygen flux onto a metal substrate to form metal oxide nucleation regions; and
providing additional oxygen flux to the nucleation regions to form the metal oxide nanowires at the nucleation regions.

27. The method of claim 26, wherein the oxygen flux is selected from a group consisting of an oxygen plasma beam, a focused oxygen beam or an electrochemically generated oxygen flux.

28. The method of claim 26, wherein:
the substrate comprises a zirconium containing substrate; and
the metal oxide nanowires comprise zirconium oxide nanowires.
